(19) United States
(12) Patent Application Publication
(10) Pub. No.: US 2006/0137978 A1
(43) Pub. Date: Jun. 29, 2006

(54) Arc evaporation device

(76) Inventor: Hermann Curtins, Grenchen (CH)

Correspondence Address: DENNISON, SCHULTZ, DOUGHERTY & MACDONALD, 1727 KING STREET, SUITE 105, ALEXANDRIA, VA, 22314, US

(21) Appl. No.: 10/537,087

(22) PCT Filed: Dec. 2, 2003
(86) PCT No.: PCT/EP03/13556

§ 371 Date: Dec. 5, 2005

(30) Foreign Application Priority Data
Dec. 2, 2002 (DE) 10256417.5

(51) Int. Cl. C23C 14/00; C23C 14/32

(52) U.S. Cl. 204/298.41; 204/192.38

(57) ABSTRACT

An arc evaporation device including a cathode target surrounded by a housing that forms the anode. In order to achieve a uniform evaporation of the target material, several electrically conductive second connections (84, 86) originate from the housing, these connections being linked by a second conductor (74) fixing an envelope having a geometry corresponding to the envelope of the target or that of a first conductor (72), which links the electric connections (76, 78) of the target.

The invention relates to an arc evaporation device with a target forming a primary pole such as a cathode, which is arranged in a housing forming a secondary pole such as an anode, wherein the target is connected to a fastener at least peripherally in an electrically conducting manner and wherein from the fastener and/or the target preferably several electrically conducting primary connections extend in the peripheral area of the target, which in turn are connected via an electrically conducting primary conductor leading to a power supply unit arranged outside the housing, with the housing being connected to said conductor via at least one electrically conducting secondary connection.

EP 0 306 491 B1 reveals a device of the above-mentioned kind. In order to apply an alloy layer to a component a target is used, which comprises at least two different metals in various active surface sections of the target.

U.S. Pat. No. 5,203,980 relates to a generic arc evaporation device comprising a target, in the peripheral area of which several power terminals are provided, which extends from a fastener of the target in an evenly distributed fashion.

In an arc evaporation device pursuant to DE 42 43 592 A1 the power is supplied to the target via a magnet coil so as to move the arc spot along a random path.

Regardless of the type of circuitry of the magnet and/or the configuration of the target forming the cathode, power is supplied to it selectively with the consequence that different impedance levels to the power terminal result as a function of the position of the arc spot on the target. This impedance variation causes the arc to become increasingly ramified and as a result droplets are increasingly emitted from the target surface. Such droplets lead to a roughening of the surface of the part that is supposed to be coated and hence an undesirable loss in quality of the layer. The variation in the impedance, i.e. the change in the electric arc voltage with a specified arc current, in particular due to losses in the supply and outflow of current, is all the more crucial since these are not detected by the control system/control electronics, and therefore the operator of the system has no influence on the reproducibility and quality.

The housing, which forms the second pole, especially the anode of the arc evaporation device, is typically connected to the power connection or the power supply unit via a point referred to as an electrically conducting secondary connection. The housing, which is generally made of stainless steel, as such is a relatively poor conductor. As a function of the location where the arc spot is located, the current must travel more or less long paths in the housing wall in order to reach the secondary connection, via which the current flows off. This way losses in potential arise, which likewise lead to an influence on the arc current that cannot always be controlled, thus leading possibly to an uncontrolled movement of the arc spot on the target.

It is the object of the present invention to further develop an arc evaporation device of the above-mentioned kind such that for one desired uniform evaporation of the target material occurs regardless of the location of the arc spot and that secondary losses in potential occurring independently from the location of the arc spot are minimized especially by the current flowing along the housing.

Pursuant to the invention, the object is essentially achieved in that several electrically conducting secondary connections extend from the housing that are connected among each other via an electrically conducting second conductor and fix at least one envelope or at least a partial envelope, whose geometry corresponds to the envelope of the target and/or of envelopes formed by the electrically conducting primary connections. In particular the second envelope fixed by the secondary connections runs concentrically or roughly concentrically to the first envelope formed by the target or to the third envelope fixed by the primary connections. Furthermore the primary connections are intended to fix a first plane, the secondary connections to fix a second plane, and the first and the second planes are intended to run parallel or roughly parallel to each other, wherein especially the envelopes run with their centers along a normal line extending from the first or second plane.

The secondary electric connections are in turn connected outside the housing to the power supply unit via a conductor designed as a ring, specifically a closed ring. To the extent that the target and/or the fastener of the target are likewise connected to the power supply unit via several electrically conducting primary connections, these are connected among each other outside the housing via a conductor designed as a ring, especially a closed ring.

The secondary connections running along an outer surface of the housing are connected thereto especially by means of welding or a screw connection and preferably have an annular or sleeve-shaped geometry with an inside thread in order to fix the ring conductor by means of a screw element that can be screwed into said conductor and connect it to the secondary connection in an electrically conducting manner.

The primary connections, which can be pins, screws, rivets, bolts or the like, extend all the way into the area of a carrier plate accommodating the carrier and are, as mentioned, connected on the outside specifically with a ring conductor consisting of copper. This way the electrically conducting primary connections are arranged in relation to the target in such a way that the same or substantially the same impedance level prevails on the target basically regardless of the position of the arc spot, of course with constant parameters such as pressure, bias etc.

Since several electrically conducting secondary connections, which peripherally quasi surround the target in a spaced manner, are assigned opposite the target and extending from an outer housing wall, the current flowing between the cathode and anode can flow off directly via one of the secondary connections with the consequence that the losses in potential outside the plasma are minimized. This results in optimized conditions for the current position of the arc spot with the result that reproducible optimal evaporation of target material with even removal of the same can take place.

If both secondary and primary connections are available, pursuant to the invention, current is always directly supplied to the location of the target at which an arc spot develops, and/or current flows off directly without having to flow through the longer sections of the housing, leading to even impedance levels as well as minimal losses of the potential.

Because of this there is little interference with the magnetic field acting upon the arc spot so that even removal of the target and/or its evaporation take place in the desired extent without the risk of drops being separated from the target and reaching the vacuum chamber surrounded by the housing, which otherwise could lead to an irregular or rough surface of a substrate that is supposed to be coated. This way an optimal fastening and/or guidance effect of the magnetic field acting upon the arc spot can be achieved. Additional optimal target erosion is accomplished, which leads to cost savings on the target material. Further details, advantages and features of the invention result not only from the claims, the features disclosed therein—either alone and/or in combination, but also from the following description of preferred design examples shown in the drawing.

They show:

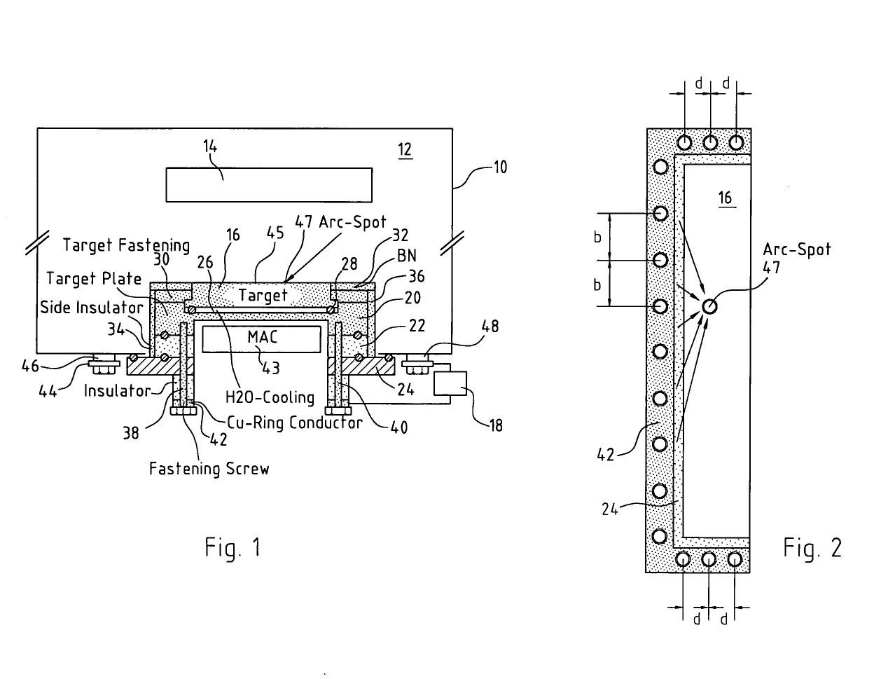

FIG. 1 a representative illustration of an arc evaporation device,

FIG. 2 a representative illustration of a target with arc spot,

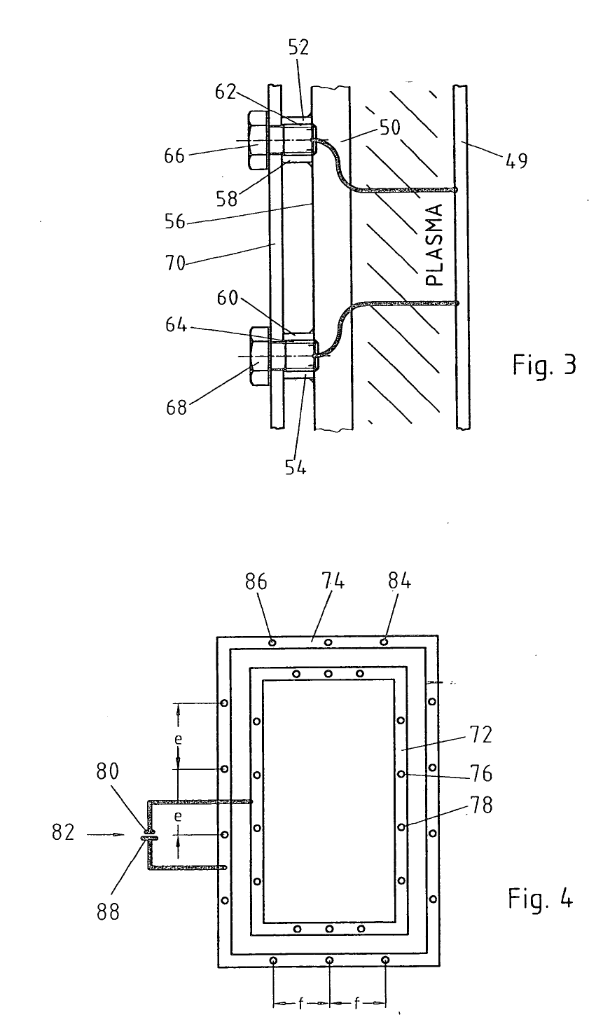

FIG. 3 a section of a target and a housing section, in a representative illustration, and

FIG. 4 representative illustrations of ring conductors that are connected to the target and/or the housing in an electrically conducting manner.

FIG. 1 shows a representative illustration of an arc evaporation device with a vacuum chamber 12 surrounded by a housing 10 for the purpose of treating, such as coating, substrate 14 located in the vacuum chamber 12. Etching is possible as well. In the design example, however, a hard material coating device shall be described as the application.

In order to coat the substrate 14, which can be arranged on a rotary table, material is evaporated from a target 16 present in the vacuum chamber 12, such as a titanium target or another suitable target, wherein said material reacts with the introduced reaction gas such as N₂ or C₂H₃ and then deposits on the substrate 14 in the desired extent. For this purpose voltage is connected between the target 16 and the housing 10 via a power supply unit 18, wherein the housing 10 is the anode and the target 16 the cathode. In this respect reference is made, however, to sufficiently known techniques, as is with respect to the applied tension of e.g. an order of magnitude of 20 V and a current in the order of magnitude of 100 A. The pressure in the vacuum chamber 12 can range from 0.0001 to 0.1 bar depending on the application, just to mention some numbers by way of example.

The target 16 extends from a carrier 20, which is insulated electrically in turn via an insulator 22 from a flange plate 24, for example made of aluminum, which in turn is connected to the housing 10. Between the target 16 and the carrier 20 a space 26 exists, to which cooling fluid such as liquid is applied in order to cool the target 16 as desired. The target 16 comprises on the bottom a peripheral flange in order to be fixed between the carrier 20 and a fastening plate 30. Between the target 16 and the carrier 20 a peripheral O-ring 28 is arranged to ensure a seal between the atmosphere and the vacuum chamber. The fastening plate 30 as such is covered by an insulator 32, for example made of BN, and connected to the base plate 24 by means of insulator 34, 36 and protected.

The carrier 20, fastening plate 30 and target 16 are connected via bolts or screws 38, 40 designed as electrically conducting primary connections or similarly acting elements in an electrically conducting manner to a connection 42, which is designed as a ring conductor, i.e. connects the screws or bolts 38, 40 among each other and connects them to the power supply unit 18. The other pole of the power supply unit 18 leads to the housing 10 via a ring conductor 44.

The housing 10 forms the anode and the carrier 20, the cover plate 30 and the target 16 form the cathode wherein, however exclusively, the target 16 is exposed with its surface 42 to the vacuum chamber 12 so that an arc and hence an arc spot 47 can develop between the anode and the target 16, the movement of which along the surface 42 is determined by a magnet 43 (MAC=Magnetic Arc Confinement), i.e. its magnetic field, located beneath the target 16 and outside the chamber 12.

Pursuant to the invention a plurality of electrically conducting primary connections in the form of e.g. bolts or screws 38, 40, which end in the peripheral area of the target 16 and are connected to the power supply unit 18 via the ring conductor 42, extend through the insulator 22 to the fastener 20 and hence to the target 16. The electrically conducting primary connections hereby have the same distance to each other, specifically at least in sides of the target 15 running parallel to each other.

When the target 16 has a rectangular geometry in the top view, the connections should likewise fix an envelope with a rectangular geometry. This results in essentially a uniform impedance level regardless of the position of the arc spot on the surface 42 with the consequence that uniform evaporation of the target 16 takes place and hence the substrates 14 to be treated and/or coated have the desired surface quality.

FIG. 2 is a representative illustration of a bottom view of the target 16 with the ring conductor 42, indicated in principle, and the base plate 24. Basically the electrically conducting connections 38, 40 extending from the ring conductor 42, designed in particular as screws, are shown, illustrating that they run along the longitudinal edges of the target 16 at the same distance to each other, wherein the distance of the screws 38, 40 along parallel edges should be the same (see equivalent distances b or d in the area of the side or edges running parallel to each other).

The ring conductor 42 consists as mentioned above preferably of copper, while the screws or similarly acting connections 38, 40 can consist of brass.

In order to accomplish a desired uniform current distribution, furthermore, a film consisting of electrically conducting material such as a copper foil should be provided between the target 16 and the carrier 20 and possibly the fastening plate 30.

In order to minimize losses in potential, which can occur through the material housing in the form of stainless steel, in the design example the target 16 and/or the envelope fixed by the electrically conducting primary connections in the form of bolts or screws 38, 40 are surrounded by electrically conducting secondary connections 46, 48, which are connected among each other via the ring conductor 44, which likewise preferably consists of copper and is in turn connected to the power supply unit 18. Hereby the electrically conducting secondary connections 46, 48 fix an envelope that runs concentrically to the envelope fixed by the electrically conducting primary connections 38, 40. This is illustrated in principle also by the images in FIGS. 1 and 4.

In FIG. 3 a section of a target 49 with an assigned housing wall 50 is shown. Along the outer wall 50 and in accordance with the explanations provided in connection with FIG. 1, electrically conducting secondary connections 52, 54 are provided on the wall or its outer wall 56 concentrically to the electrically conducting primary connections 38, 40, wherein said secondary connections can consist e.g. of brass or stainless steel. They comprise annular or sleeve-shaped primary sections 58, 60 that are welded to the outer surface 56 and comprise inside threads 62, 64 in order to be able to screw in fastening devices such as crews 66, 68, preferably brass screws. Between each screw head and outer surface of the section 58, 60 then a conductor 70 such as Cu strip runs, which connects the electrically conducting secondary connections 52, 54 among each other and is therefore preferably designed as a ring conductor in accordance with the conductor 42 for the target 49. The corresponding ring conductor 70 is then connected to the positive pole of a power supply unit.

FIG. 3 furthermore illustrates that the plasma arc current flowing between the target 49 and the housing 50 flows off on the shortest path via one of the electrically conducting secondary connections 52, 54 to the ring conductor 70 so that otherwise occurring losses in potential, which may occur due to the long paths traveled in the housing as a function of the location of the spot on the target 48, (remaining part of sentence missing).

The arrangement pursuant to the invention of two electrically conducting ring conductors 72, 74 extending preferably concentrically to each other, which connect the primary and secondary connections 76, 78, 84, 86 among each other, is illustrated in principle in FIG. 4. This way the ring conductor 72 connects the electrically conducting primary connections 76, 78, which lead to a target and are connected to the negative pole 80 of a power supply unit 82. The ring conductor 74 connecting the electrically conducting secondary connections 84, 86 is connected to the positive pole 88 of the power supply unit 82. These measures ensure that the current outflow does not lead to high losses in potential and that the entire electric power is used for evaporation and in the plasma.

While in the design example the ring conductors 72, 74 are designed with roughly the same geometry, but different sizes, different dimensions can also be selected.

FIG. 4 furthermore illustrates that the secondary connections 84, 86 running along a respective leg of the ring conductor have the same distance e or, as the case may be, f to each other.

1. Arc evaporation device with a target (16, 49) forming a first pole such as a cathode, which is arranged in a housing (10) forming a second pole such as an anode, wherein the target is connected to a fastener (20) at least peripherally in an electrically conducting manner and wherein from the fastener (20) and/or the target (16) preferably several electrically conducting primary connections (38, 40, 76, 78) extend in the peripheral area of the target, which in turn are connected via an electrically conducting primary conductor (42, 72) leading to a power supply unit (18, 82) arranged outside the housing, with the housing being connected to said unit via at least one electrically conducting secondary connection (44, 46, 49, 53, 54, 84, 86), is characterized in that several electrically conducting secondary connections (46, 48, 52, 54, 84, 86) extend from the housing (10), which are connected among each other via an electrically conducting secondary conductor (44, 70, 74) and fix at least one envelope or at least a partial envelope, whose geometry corresponds to the envelope of the target (16, 49) and/or of envelopes formed by the electrically conducting primary connections (38, 40, 76, 78).

2. Arc evaporation device pursuant to claim 1, is characterized in that the secondary envelope fixed by the electrically conducting secondary connections (46, 48, 52, 54, 84, 86) runs concentrically or roughly concentrically to the primary envelope fixed by the target (16) or by the third envelope fixed by the electrically conducting primary connections (38, 40, 76, 78).

3. Arc evaporation device pursuant to claim 1, is characterized in that the electrically conducting primary connections (38, 40, 76, 78) fix a first plane, that the electrically conducting secondary connections (46, 48, 52, 54, 84, 86) fix a second plane and that the first and second planes run parallel or roughly parallel to each other.

4. Arc evaporation device pursuant to claim 1, is characterized in that the normal line extending from the center of the first and/or third envelope runs through the center or roughly the center of the second envelope.

5. Arc evaporation device pursuant to claim 1, is characterized in that the electrically conducting secondary connections (46, 48, 52, 54, 84, 86) are connected outside the housing (10) to the power supply unit (18, 82) via a secondary conductor (44, 70, 74) designed as a ring, especially a closed ring.

6. Arc evaporation device pursuant to claim 1, is characterized in that the preferably peripherally designed secondary conductor (44, 70, 72) preferably consists of copper or aluminum or contains it.

7. Arc evaporation device pursuant to claim 1, is characterized in that the electrically conducting secondary connections (46, 48, 52, 54, 84, 86) preferably consist of brass or stainless steel.

8. Arc evaporation device pursuant to claim 1, is characterized in that the electrically conducting secondary connections (44, 52, 54, 84, 86) extend from the outside of the housing and in particular are welded to it.

9. Arc evaporation device pursuant to claim 1, is characterized in that the electrically conducting secondary connections (52, 54) comprise annular or sleeve-shaped elements (58, 60) with inside threads (62, 64), which are attached such as welded to an outer surface (56) of the housing (50), that connecting elements such as screw elements (66, 68) can be screwed into the inside threads and that between the annular or sleeve-shaped elements and the screw elements the secondary conductor (70) such as a ring conductor runs, which is in turn connected to the power supply unit (18, 82).

10. Arc evaporation device pursuant to claim 1, is characterized in that the electrically conducting primary connections (38, 40) are connected outside the housing (10) to the power supply unit (18, 82) via the primary conductor (42) designed as a ring, especially a closed ring.

11. Arc evaporation device pursuant to claim 1, is characterized in that the electrically conducting primary connections (38, 40) are directed such at the target (16) that the same or substantially the same impedance level prevails regardless of the position of the respective arc spot (44).

12. Arc evaporation device pursuant to claim 1, is characterized in that a film consisting of electrically conducting material, especially a copper foil, is arranged between the target (16) and the fastener (20).

13. Arc evaporation device pursuant to claim 1, is characterized in that the preferably peripherally designed primary conductor (42) preferably consists of copper or aluminum or contains it.

14. Arc evaporation device pursuant to claim 1, is characterized in that the electrically conducting primary connections leading to the fastener (20) and/or the target (16) are in particular screws or bolts (38, 40), which preferably consist of brass.

15. Arc evaporation device pursuant to claim 2, is characterized in that the third envelope fixed by the electrically conducting primary connections has the circumferential geometry of the target (16) and extends preferably coaxially thereto.

16. Arc evaporation device pursuant to claim 2, is characterized in that the third envelope fixed by the electrically conducting primary connections has a square geometry, wherein along each leg the distance (b, d) between the electrically conducting primary connections is the same or substantially the same.

17. Arc evaporation device pursuant to claim 1, is characterized in that the secondary envelope fixed by the electrically conducting secondary connections (84, 86) has a square geometry, wherein along each leg the distance (e, f) between the electrically conducting secondary connections is the same or substantially the same.
